(19) United States
(12) Patent Application Publication
(10) Pub. No.: US 2025/0070489 A1
(43) Pub. Date: Feb. 27, 2025

(54) CONNECTOR

(71) Applicant: SUMITOMO WIRING SYSTEMS, LTD., Mie (JP)

(72) Inventor: Yoshiharu SATO, Mie (JP)

(21) Appl. No.: 18/796,931

(22) Filed: Aug. 7, 2024

(30) Foreign Application Priority Data
Aug. 23, 2023 (JP) 2023-135624

(51) Int. Cl. H01R 12/70; H01R 12/88

(52) U.S. Cl. CPC H01R 12/7023; H01R 12/88; H01R 2201/26

(57) ABSTRACT

A connector 10 that is attached to a substrate 11 that is housed in a case C includes: a housing including a fitting portion 20 for a mating connector 50, the fitting portion 20 being open forward; and terminal fittings 13 that include substrate connection portions 15 that extend rearward from the housing 12, wherein a wall 24 of the housing 12 on an inner side of the case C includes an opening 30 that passes through the wall 24 in a thickness direction thereof, and a lower surface 32 that is included in peripheral surfaces that define the opening 30 is inclined downwards in a direction towards an outside of the case C.

### CROSS-REFERENCE TO RELATED APPLICATIONS

This application is based on and claims priority from Japanese Patent Application No. 2023-135624, filed on Aug. 23, 2023, with the Japan Patent Office, the disclosure of which is incorporated herein in its entirety by reference.

### TECHNICAL FIELD

The present invention relates to a connector.

### BACKGROUND

For example, as described in JP 2019-153546 A, JP 2008-130359 A, and JP 2020-080237 A, conventional connectors that are attached to a case that houses a substrate are known. The connector described in JP 2019-153546 A includes a housing that is provided with a fitting portion for a mating connector and a terminal fitting that extends rearward from a rear wall of the housing and is connected to a substrate. A rear portion of the housing and the substrate are housed in a case with the connector attached to the case. An opening is formed in the rear wall of the housing.

### SUMMARY

Such a connector may be tilted during use. It is desired to prevent water from entering the case through the opening in the housing, even when the connector is tilted.

Therefore, the present disclosure aims to provide a connector capable of preventing water from entering the inside of the case, even when the connector is tilted.

A connector according to the present disclosure is a connector that is attached to a substrate that is housed in a case, including: a housing that includes a fitting portion for a mating connector, the fitting portion being open forward; and terminal fittings that include substrate connection portions that extend rearward from the housing, wherein a wall of the housing on an inner side of the case is provided with an opening that passes through the wall in a thickness direction thereof, and a lower surface that is included in peripheral surfaces that define the opening is inclined downwards in a direction towards an outside of the case.

With the present disclosure, it is possible to provide a connector that is capable of preventing water from entering the case, even when the connector is tilted.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a side view showing a connector according to an embodiment when fitted to a mating connector.

FIG. 2 is a front view showing the connector when not fitted to the mating connector.

FIG. 3 is a rear view showing the connector when fitted to the mating connector.

FIG. 4 is a cross-sectional view showing the connector and corresponding to a cross section taken along A-A in FIG. 2.

FIG. 5 is a cross-sectional view showing the connector and corresponding to a cross section taken along B-B in FIG. 3.

FIG. 6 is a partially enlarged cross-sectional view enlarging an opening and a cam pin shown in the cross-sectional view in FIG. 5.

FIG. 7 is a diagram illustrating entrance of water into the fitting portion.

FIG. 8 is a diagram illustrating a reason why water can be prevented from entering the case, even when the connector is tilted to a rear side.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

### Description of Embodiments of Present Disclosure

First, embodiments of the present disclosure will be listed and described.

(1) A connector according to the present disclosure is a connector that is attached to a substrate that is housed in a case, including: a housing that includes a fitting portion for a mating connector, the fitting portion being open forward; and terminal fittings that include substrate connection portions that extend rearward from the housing, wherein a wall of the housing on an inner side of the case is provided with an opening that passes through the wall in a thickness direction thereof, and a lower surface that is included in peripheral surfaces that define the opening is inclined downwards in a direction towards an outside of the case. With this configuration, water is less likely to flow towards the inside of the case along the lower surface of the opening, even when the connector is tilted. Therefore, it is possible to prevent water from entering the case.

(2) In the connector described in (1) above, an upper surface that is included in the peripheral surfaces that define the opening may be inclined downwards in the direction towards the outside of the case. With this configuration, water is less likely to flow towards the inside of the case along the upper surface of the opening and remains inside the connector, even when the connector is tilted. Therefore, it is possible to prevent water from entering the case.

(3) In the connector described in (1) or (2) above, the housing may include a cam pin configured to engage with a lever that is provided in the mating connector, the opening may be formed in a rear wall of the housing and is positioned rearwards of the cam pin, a lower end of the upper surface of the opening may be positioned higher than an upper end of the cam pin, and an upper end of the lower surface of the opening may be positioned lower than a lower end of the cam pin. With this configuration, even if the upper surface and lower surface of the opening are tilted, the cam pin can be molded using front and rear molds in the same manner as with the conventional techniques. Therefore, it is possible to prevent water from entering the case without complicating the molds.

(4) In the connector described in any one of (1) to (3) above, a lower surface that is included in an inner surface of the fitting portion may include an inclined portion that is inclined downwards in a forward direction, and the inclined portion may increase a gap between the lower surface of the fitting portion and the mating connector in a state of being fitted to the fitting portion, in the forward direction. With such a configuration, when the connector is not tilted to the rear side, the water inside the fitting portion flows along the inclined portion and is discharged to the outside of the fitting portion, and therefore, water is less likely to remain inside the fitting portion.

### Details of Embodiments of Present Disclosure

Specific examples of the connector according to the present disclosure will be described below with reference to the drawings. Note that the present invention is not limited to these examples, but is indicated by the scope of the claims, and is intended to include all changes within the meaning and scope equivalent to the scope of the claims.

### First Embodiment

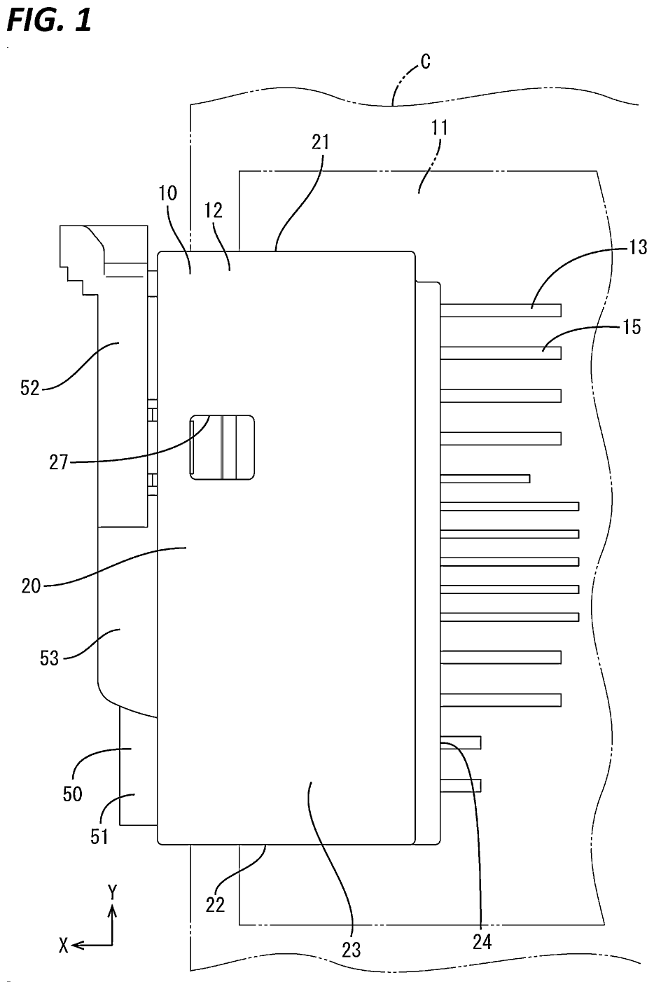

A connector 10 according to a first embodiment of the present disclosure is attached to a substrate 11 that is housed in a case C. As shown in FIG. 1, the connector 10 can be fitted to a mating connector 50.

Hereinafter, in the description of the connector 10, the front side in the direction in which the connector 10 is fitted to the mating connector 50 will be referred to as the front side. The vertical direction is based on the vertical direction in a state where the connector 10 is installed. The state where the connector 10 is installed is a state where a rear wall 24 is vertical, and in this state, the direction in which the connector 10 is fitted to the mating connector 50 is horizontal. The left-right direction is based on the left-right direction when the connector 10 is viewed from the front side. In each figure, the positive side of the X axis indicates the front side, the negative side of the X axis indicates the rear side, the positive side of the Y axis indicates the top side, the negative side of the Y axis indicates the bottom side, the positive side of the Z axis indicates the left side, and the negative side of the Z axis indicates the right side.

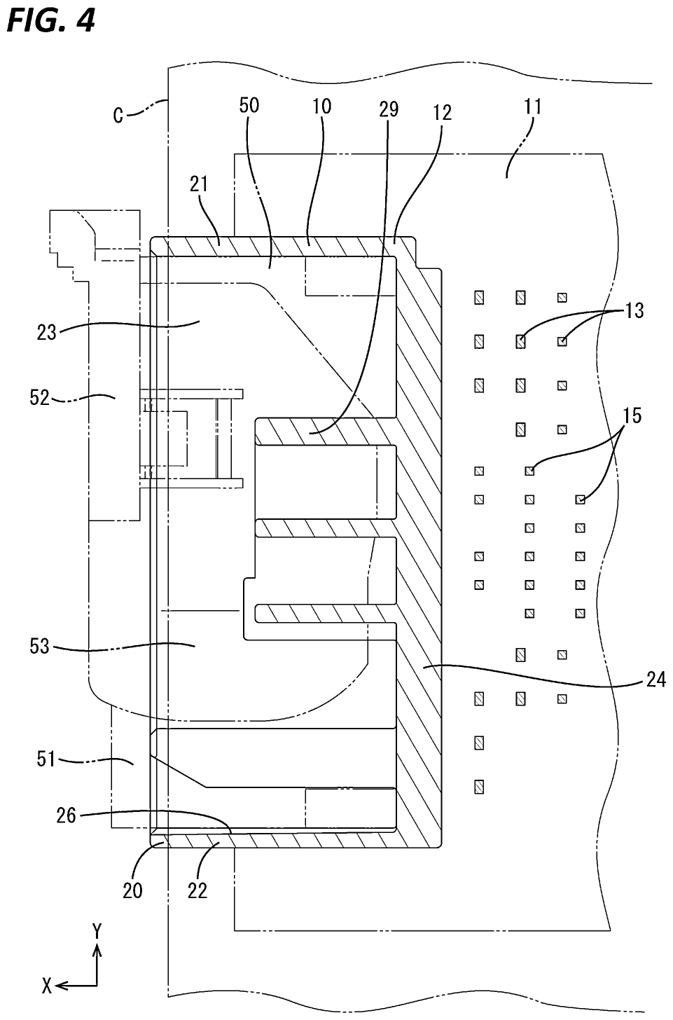

The mating connector 50 includes a mating housing 51 and a lever 52. The mating housing 51 houses a mating terminal fitting (not shown). The mating terminal fitting is a female terminal fitting, and is connected to a terminal portion of an electric wire (not shown). The lever 52 is rotated about a shaft portion (not shown). The lever 52 includes cam plates 53 (see FIG. 4). Cam grooves (not shown) are formed in the cam plates 53. When the connector 10 is fitted to the mating connector 50, cam pins 28, which will be described later, are inserted into the cam grooves. The cam pins 28 move along the cam grooves as the lever 52 is rotated. As a result, the fitting between the connector 10 and the mating connector 50 proceeds.

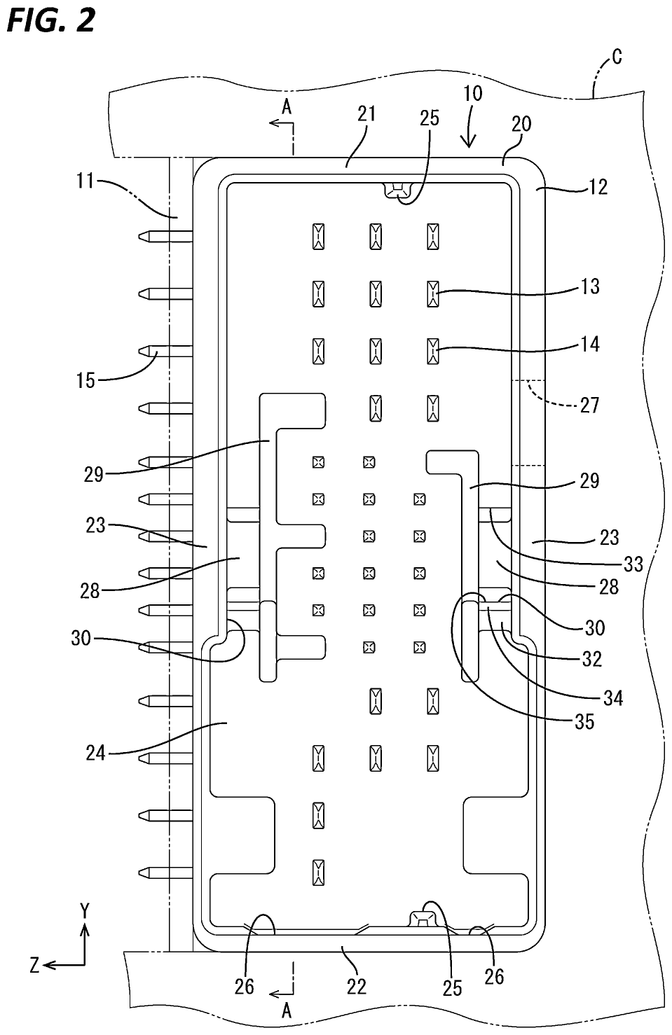

As shown in FIGS. 1 and 2, the connector 10 includes a housing 12 and terminal fittings 13. The terminal fittings 13 are connected to the substrate 11. The substrate 11 is a rigid printed wiring board. In each figure, the substrate 11 is indicated by a two-dot chain line. In a state where the connector 10 is installed, the substrate 11 is positioned vertically.

The housing 12 is made of a synthetic resin and, as shown in FIGS. 1 and 2, has an overall rectangular box shape that is elongated in the vertical direction. The housing 12 includes a fitting portion 20 for the mating connector 50. The fitting portion 20 is open forward. The mating housing 51 and the lever 52 are inserted into the fitting portion 20 from the front side.

The terminal fittings 13 are each made of a conductive metal and is L-shaped overall. The terminal fittings 13 include connection portions 14 for the mating connector and substrate connection portions 15. The connection portion 14 for the mating connector is positioned so as to protrude to the inside of the fitting portion 20. The connection portion 14 for the mating connector is connected to the mating terminal fitting when the connector 10 is fitted to the mating connector 50.

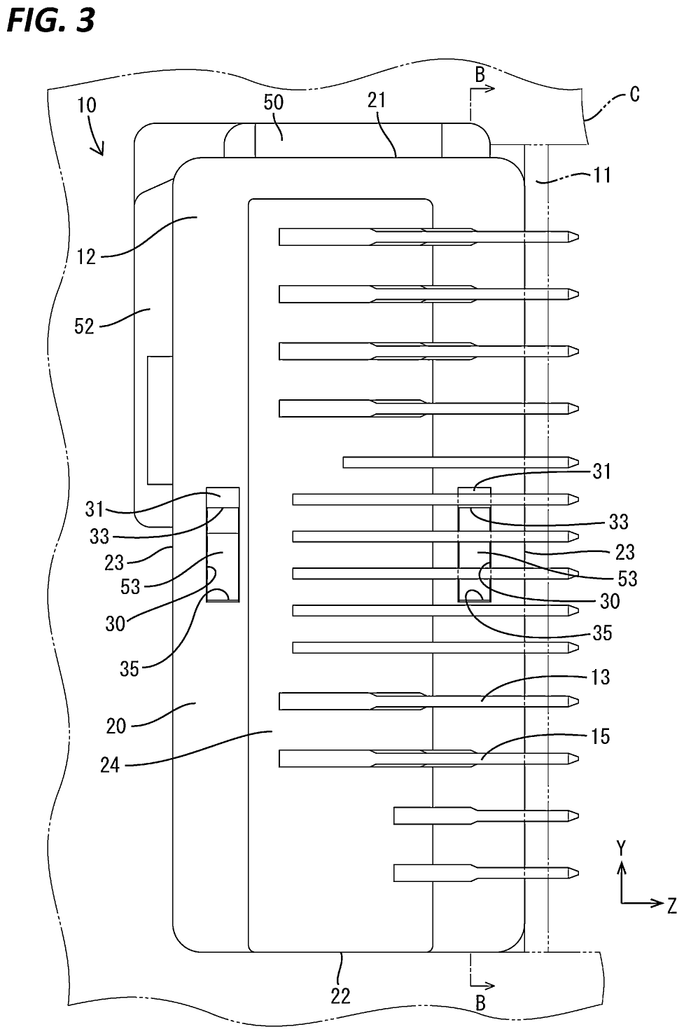

The substrate connection portions 15 extend rearward from the housing 12. The substrate connection portions 15 are each bent at a right angle in the horizontal direction at a position that is rearward of the housing 12. As shown in FIG. 3, three substrate connection portions 15 extend across the rear of one of the two openings 30, which will be described later. The substrate connection portions 15 are housed in the case C. End portions of the substrate connection portions 15 are connected to the substrate 11.

As shown in FIG. 2, the fitting portion 20 has an upper wall 21, a lower wall 22, left and right side walls 23, and a rear wall 24. The lower surface of the upper wall 21, the upper surface of the lower wall 22, the right surface of the left side wall, the left surface of the right side wall, and the front surface of the rear wall 24 constitute the inner surface of the fitting portion 20.

The upper wall 21 and the lower wall 22 are arranged horizontally. The lower surface of the upper wall 21 and the upper surface of the lower wall 22 are provided with fitting ribs 25. The positions of the upper fitting rib 25 and the lower fitting rib 25 are shifted in the left-right direction. When the mating housing 51 is inserted into the inside of the fitting portion 20, the fitting ribs 25 respectively fit into the fitting grooves (not shown) of the mating housing 51.

As shown in FIGS. 2 and 4, the upper surface of the lower wall 22 has inclined portions 26 that are inclined downwards in a forward direction. Each inclined portion 26 increases the gap between the upper surface of the lower wall 22 and the mating connector 50 in the state of being fitted to the fitting portion 20, in a forward direction. The front ends of the inclined portions 26 reach the open end of the fitting portion 20. The rear ends of the inclined portions 26 reach the rear wall 24. The inclined portions 26 are each inclined at a constant angle from the front end to the rear end.

As shown in FIG. 2, two inclined portions 26 are provided. The two inclined portions 26 are provided with an interval in the left-right direction. The width of one inclined portion 26 of the left and right inclined portions 26 is larger than the width of the other inclined portion 26. The lower fitting rib 25 is provided between the left and right inclined portions 26.

As shown in FIG. 2, the left and right side walls 23 are arranged vertically. One side wall of the left and right side walls 23 positioned opposite to the substrate 11 is provided with a locking opening 27 that passes therethrough in the left-right direction. The locking opening 27 is open in a rectangular shape (see FIG. 1). The other side wall of the left and right side walls 23 on the substrate 11 side is not provided with a hole or an opening.

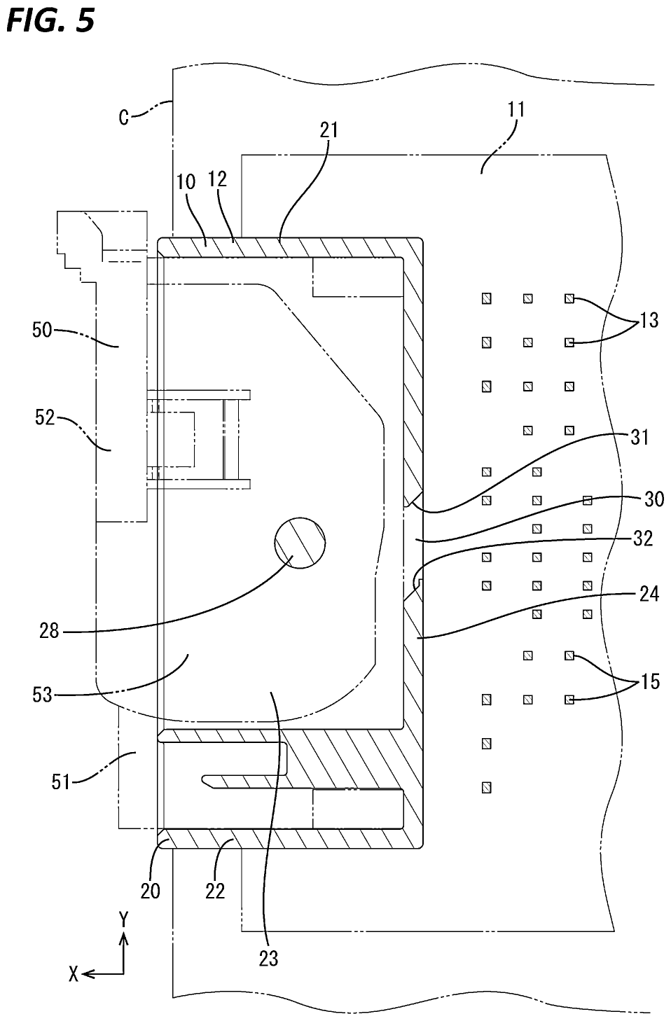

As shown in FIG. 2, the left and right side walls 23 are provided with a pair of cam pins 28. The pair of cam pins 28 protrude from the left and right side walls 23 towards the inside of the fitting portion 20. The cam pins 28 respectively engage with the cam grooves of the lever 52 included in the mating connector 50. As shown in FIG. 5, each cam pin 28 has a cylindrical shape.

As shown in FIG. 2, a pair of left and right inner walls 29 are provided inside the fitting portion 20. The inner walls 29 are provided so as to protrude forward from the rear wall 24. The left and right inner walls 29 are provided at positions closer to the center in the left-right direction than the left and right cam pins 28. The plate surfaces of the inner walls 29 are arranged parallel to the left and right side walls 23. The cam plates 53 of the lever 52 are respectively housed between the left inner wall 29 and the left side wall 23 and the right inner wall 29 and the right side wall 23.

The rear wall 24 closes the rear surface of the fitting portion 20. The terminal fittings 13 pass through the rear wall 24. In the state where the connector 10 with the substrate is attached to the case C, the rear wall 24 is housed in the case C. As shown in FIG. 2, two openings 30 are formed in the rear wall 24. The openings 30 are positioned rearwards of the cam pins 28. The centers of the cam pins 28 and the openings 30 are arranged at the same height. The openings 30 are punch holes of a mold for forming the cam pins 28. Each opening 30 has a vertically elongated rectangular shape. The left and right openings 30 have the same shape.

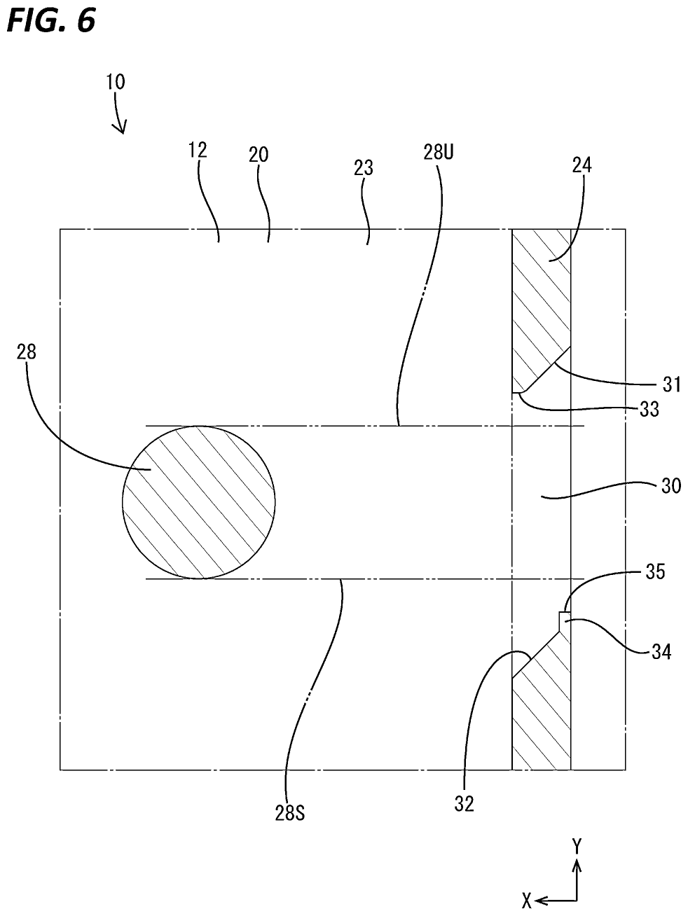

As shown in FIG. 6, the openings 30 pass through the rear wall 24 in a thickness direction (front-rear direction). An upper surface 31 and a lower surface 32 of each opening 30, included in the peripheral surfaces that define the opening 30, are both inclined downwards in a forward direction. The inclinations of the upper surface 31 and the lower surface 32 are the same. As shown in FIG. 6, a horizontal portion 33 is provided at the front end of the upper surface 31. The inclination of the upper surface 31 continues from the rear end of the opening 30 to the rear end of the horizontal portion 33. A wall-shaped portion 34 is provided at the rear end of the lower surface 32. The rear surface of the wall-shaped portion 34 is flush with the rear surface of the rear wall 24, and constitutes a portion of the rear surface of the rear wall 24. The upper surface of the wall-shaped portion 34 is a horizontal surface 35. The dimension of the horizontal portion 33 in the front-rear direction and the dimension of the horizontal surface 35 in the front-rear direction are equivalent. The inclination of the lower surface 32 is continuous from the lower front end of the wall-shaped portion 34 to the front end of the opening 30.

The lower end of the upper surface 31 of the opening 30 is positioned higher than a height position 28U of the upper end of the cam pin 28. The position of the lower end of the upper surface 31 is the height position of the horizontal portion 33. The position of the upper end of the cam pin 28 is the position of the uppermost end of the cam pin 28 in the XY cross section. The upper end of the lower surface 32 of the opening 30 is at a lower position than a height position 28S of the lower end of the cam pin 28. The position of the upper end of the lower surface 32 is the height position of the horizontal surface 35.

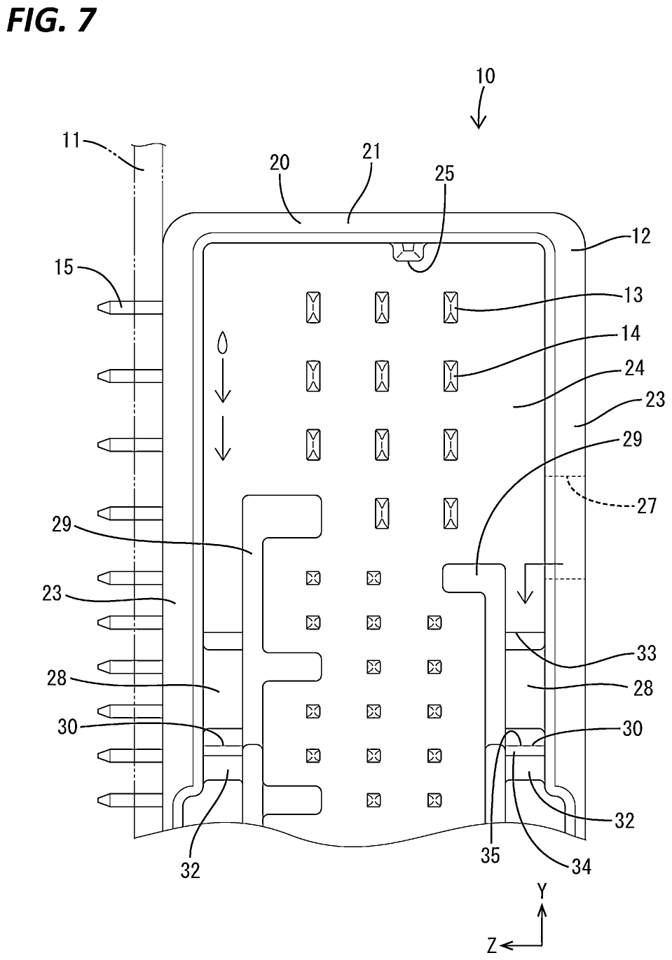

Next, the flow of water when water enters the inside of the fitting portion 20 will be described. Water may enter the inside of the fitting portion 20 through the gap between the fitting portion 20 and the mating connector 50, locking opening 27, or the like. Water that has entered the inside of the fitting portion 20 may flows along the inner surface of the fitting portion 20 as indicated by arrows in FIG. 7.

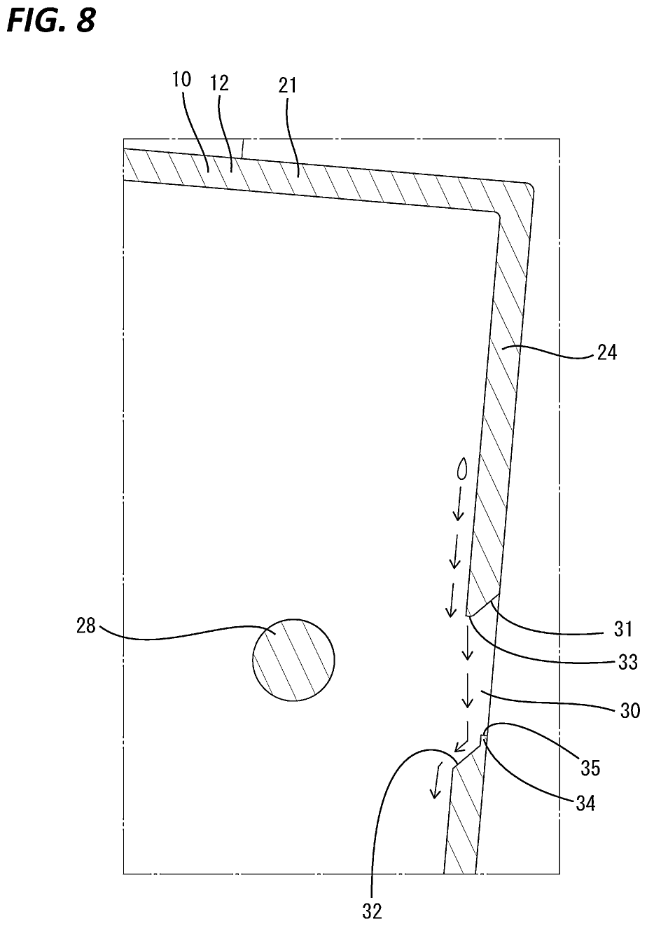

When the connector 10 is tilted to the rear side, such as when a vehicle equipped with the connector 10 is placed on a slope, in other words, when the fitting portion 20 is oriented slightly upwards, water may flow along the front surface of the rear wall 24 and reach the opening 30 from above the opening 30 as indicated by the arrows in FIG. 8. The upper surface 31 of the opening 30 is inclined upwards in a rearward direction, even when the connector 10 is tilted towards the rear side. Therefore, water is prevented from entering the inside of the case C along the upper surface 31 of the opening 30. The water that has reached the opening 30 from above is likely to fall downwards from the lower end of the upper surface 31.

Water may reach the lower surface 32 of the opening 30, such as by falling from the lower end of the upper surface 31. The lower surface 32 of the opening 30 is inclined upwards in a rearward direction, even when the connector 10 is tilted towards the rear side. Therefore, water is prevented from entering the inside of the case C along the lower surface 32 of the opening 30. The water that has reached the lower surface 32 of the opening 30 flows into the inside of the fitting portion 20 due to the inclination of the lower surface 32.

When the connector 10 is not tilted towards the rear side, the water inside the fitting portion 20 may flow forward along the inclined portions 26 provided on the lower wall 22 of the fitting portion 20 and be discharged to the outside of the fitting portion 20 from the front end of the fitting portion 20. This makes it less likely that water will remain inside the fitting portion 20.

Next, the operation and effects of the embodiment with the above-described configuration will be described. A connector 10 is attached to a substrate 11 and is housed in a case C. The connector 10 includes a housing 12 and terminal fittings 13. A fitting portion 20 for a mating connector 50 of the housing 12 is open forward. The terminal fittings 13 include substrate connection portions 15 that extend rearward from the housing 12. A rear wall 24 of the housing 12, which faces the inside of the case C, is provided with an opening 30 that passes through the rear wall 24 in a thickness direction thereof. A lower surface 32 included in peripheral surfaces that define the opening 30 is inclined downwards in a forward direction (towards the outside of the case C). With this configuration, water is less likely to flow rearwards (towards the inside of the case C) along the lower surface 32 of the openings 30, even when the connector 10 is slightly tilted to the rear side. Therefore, it is possible to prevent water from entering the case C.

An upper surface 31 included in the peripheral surfaces that define the opening 30 is also inclined downwards in a forward direction (towards the outside of the case C). With this configuration, water is less likely to flow rearwards (towards the inside of the case C) along the upper surface 31 of the openings 30, even when the connector 10 is tilted to the rear side. Therefore, it is possible to prevent water from entering the case C.

The housing 12 is provided with a cam pin 28 that engages with a lever 52 included in the mating connector 50. The openings 30 is formed in the rear wall 24 of the housing 12 and is positioned rearwards of the cam pin 28. The lower end of the upper surface 31 of the opening 30 is positioned higher than the upper end of the cam pin 28. The upper end of the lower surface 32 of the opening 30 is at a lower position than the lower end of the cam pin 28. With this configuration, even if the upper surface 31 and lower surface 32 of the opening 30 are tilted, the cam pin 28 can be molded using front and rear molds in the same manner as with the conventional techniques. Therefore, it is possible to prevent water from entering the case C without complicating the molds.

A lower surface included in the inner surface of the fitting portion 20 includes an inclined portion 26 that is inclined downwards in a forward direction. The inclined portion 26 increases the gap between the lower surface of the fitting portion 20 and the mating connector 50 in the state of being fitted to the fitting portion 20, in a forward direction. With this configuration, when the connector 10 is not tilted to the rear side, the water inside the fitting portion 20 is discharged to the outside of the fitting portion 20 along the inclined portion 26.

### Other Embodiments of Present Disclosure

The embodiments disclosed herein should be considered to be illustrative in all respects and not restrictive.

In the above embodiment, the openings are provided in the rear wall, but in another embodiment, the openings may be provided in the rear end portions (portions facing the inside of the case) of the left and right side walls. In this case, it is possible to prevent water from entering the inside of the case when the connector is tilted to the left or right, by tilting the lower surfaces of the openings downwards in a direction towards the side (the inside of the fitting portion) opposite to the side facing the inside of the case.

In the above embodiment, the upper surfaces of the openings are tilted, but in another embodiment, the upper surfaces of the openings may be horizontal, for example.

In the above embodiment, the inclined portions are provided on the lower wall of the fitting portion, but in another embodiment, inclined portions may not be provided on the lower wall of the fitting portion.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A connector that is attached to a substrate that is housed in a case, comprising:
a housing that includes a fitting portion for a mating connector, the fitting portion being open forward; and
terminal fittings that include substrate connection portions that extend rearward from the housing,
wherein a wall of the housing on an inner side of the case is provided with an opening that passes through the wall in a thickness direction thereof, and
a lower surface that is included in peripheral surfaces that define the opening is inclined downwards in a direction towards an outside of the case.

2. The connector according to claim 1,
wherein an upper surface that is included in the peripheral surfaces that define the opening is inclined downwards in the direction towards the outside of the case.

3. The connector according to claim 2,
wherein the housing includes a cam pin configured to engage with a lever that is provided in the mating connector,
the opening is formed in a rear wall of the housing and is positioned rearwards of the cam pin,
a lower end of the upper surface of the opening is positioned higher than an upper end of the cam pin, and
an upper end of the lower surface of the opening is positioned lower than a lower end of the cam pin.

4. The connector according to claim 1,
wherein a lower surface that is included in an inner surface of the fitting portion includes an inclined portion that is inclined downwards in a forward direction, and
the inclined portion increases a gap between the lower surface of the fitting portion and the mating connector in a state of being fitted to the fitting portion, in the forward direction.
